(19) United States
(12) Patent Application Publication
(10) Pub. No.: US 2002/0175424 A1
(43) Pub. Date: Nov. 28, 2002

(54) Process of forming metal surfaces compatible with a wire bonding and semiconductor integrated circuits manufactured by the process

(76) Inventors: Vaidyanathan Kripesh, Singapore (SG); Mahadevan K. Iyer, Singapore (SG); Thiam Beng Lim, Singapore (SG)

Correspondence Address: KNOBBE MARTENS OLSON & BEAR LLP, 2040 MAIN STREET, FOURTEENTH FLOOR, IRVINE, CA, 92614, US

(21) Appl. No.: 10/078,243

(22) Filed: Feb. 14, 2002

Related U.S. Application Data
(60) Provisional application No. 60/269,500, filed on Feb. 16, 2001.

(51) Int. Cl. H01L 23/48

(52) U.S. Cl. 257/779

(57) ABSTRACT

The present invention relates to the structure and process of forming metal surfaces on the bare metal interconnect of a semiconductor chip. The metal chip comprises metal interconnect formed on a semiconductor substrate and at least a portion of the metal interconnect is exposed to the environment. In one aspect of the invention, the process comprises applying a noble metal on the exposed portion of the metal interconnect and performing a chemical process that causes a layer of the noble metal to convert into a bondable layer compatible with a conventional wire bonding. The process also comprises bonding a metal wire to the bondable layer.

### CROSS-REFERENCE TO RELATED APPLICATIONS This application claims the benefit of U.S. provisional patent application No. 60/269500, filed on Feb. 16, 2001, under § 119 (e).

### BACKGROUND OF THE INVENTION

1. Field of the Invention

The invention relates to a process of manufacturing a semiconductor integrated circuit and, in particular, a process of forming an electrical connection between a metal wire and a metal interconnect in the semiconductor circuit:

2. Description of the Related Technology

Wire bonding has been the predominate structure for connecting to a semiconductor interconnects and it is used in a significant share of all leaded packages. Briefly, a wire bonding is a low-temperature welding process. As an alternative technique to welding, conventional wire bonding uses ultrasonic energy that is applied through a bonding tool (called a capillary or wedge) to a wire and a bond site. This energy increases the dislocation density of the wire and bond site, lowering flow stress and modulus of elasticity while increasing the rate of diffusion. This causes the material to deform easily at much lower stresses than would otherwise be required.

Presently, with the development of copper chip technology by various semiconductor companies, the fabrication of microprocessors, digital signal processors, memories, and other semiconductor circuits will be made by using advanced copper interconnects. With INTEL's launch of the PENTIUM II microprocessor, which is code named Copper Mine, other manufacturers, such as AMD and MOTOROLA, have launched their own processors based on copper metal. This has brought about new challenges in the packaging of a copper chip using conventional wire bonding technology. With conventional wire bonding technology, when the copper chip is mounted on the carrier substrate using a die bonding process generally cured at a temperature of 125° C. and a subsequent wire bonding process is performed at 110-180° C., it causes oxidation of the copper metallization and forms improper ball bonding. The conventional gold/aluminum wire bonding in such a case has a very low bond strength. Another approach is to use a wire bonding with a reduction atmosphere by purging the bond with N₂/H₂ gas, but such an approach is more complex and not cost effective.

As one example of known wire bonding technology, an advanced copper interconnect system (U.S. Pat. No. 5,785,236 entitled “Advanced Copper Interconnect System Compatible With Existing Bonding Technology”) is illustrated in FIG. 1. A gold wire bonding (gold wire not shown) is carried out by applying an aluminum pad 13 over a copper interconnects 12 and a dielectric 11. These are deposited on a silicon wafer 10, through an opening formed on a passivation layer 14. As shown in FIG. 1, this additional cap metallization (aluminum pad 13) process enables electrical connections to be formed between the gold wire (not shown) and the copper interconnects 12 through the aluminum pad 13. The system enables the conventional wire bonding techniques to be employed on the copper interconnects 12. However, the additional step of forming the aluminum pad 13 involves a complicated semiconductor fabrication process such as a lithography step and a chemical etching step, which increases manufacturing cost.

Another known bonding technique is depicted in FIG. 2 (U.S. Pat. No. 6,020,048 entitled “Thick film circuit board and method of forming wire bonding electrode thereon”). A copper thick film 21 (Cu conductor) is screen printed as a wiring layer on a ceramic substrate 20. Then, a thick gold film paste 22 (Au conductor) is screen printed at bonding locations on the substrate 20 such that at least a part of the thick gold film paste 22 is overlapped with the Cu conductor 21. Thereafter, a silicon chip 23 is bonded to the ceramic substrate 20 by an adhesive agent or die bond 24, and the silicon chip 23 is bonded to the thick gold film paste 22 by a Au or Al wire 25. The structure shown in FIG. 2 permits a gold/aluminum bonding by using conventional wire bonding. However, this method is applicable to only the copper metallization in the substrate 20, while the silicon chip 23 has conventional aluminum or gold wire compatible metallization. Secondly, it needs a mask and an additional screen printing process, aside from the fact that printing of gold material is not a cost-effective process.

Another known bonding technique is disclosed in U.S. Pat. No. 6,034,422 and Singapore Patent SG60018A1 (entitled “Lead Frame, method for partial noble plating of said lead frame and semiconductor device having said lead frame”). Referring to FIG. 3, a silver layer 32 is provided on a copper lead frame 31. A silicon chip 33 is bonded to a die pad 36 by an adhesive agent 34 (die bond) and the silicon chip 33 is bonded to the silver layer 32 by a wire 35 (wire bond). The silver layer 32 prevents oxidation of the copper lead frame 31 by providing a thin silver plating on the copper lead frame 31. This silver layer 32 will enhance the molding of the devices. However, this process is restricted to the copper lead frame area and the semiconductor device is considered to have a compatible metallization to the conventional Au and Al bonding wire.

### SUMMARY OF CERTAIN INVENTIVE ASPECTS

One aspect of the present invention is to provide a process of forming metal surfaces on a bare metal chip. The metal chip includes metal interconnects formed on a semiconductor substrate and at least a portion of the metal interconnects is exposed to the environment. The process comprises applying a noble metal on the portion of the exposed metal interconnect and performing a chemical process that causes a layer of the noble metal to convert to a bondable layer compatible with a wire bonding. The process also comprises bonding a metal wire to the bondable layer.

Another aspect of the present invention is to provide a process of forming metal surfaces on a bare metal chip. The metal chip includes a metal interconnect formed on a semiconductor substrate and at least a portion of the metal interconnect is exposed to the environment. The process comprises depositing a layer of a low melting point metal whose melting temperature is relatively low on the portion of the exposed metal interconnect. The process also includes performing a chemical process that causes the layer of the low melting point metal to convert into a bondable layer compatible with a wire bonding. The process also comprises bonding a metal wire to the bondable layer.

Another aspect of the present invention is to provide a process of forming metal surfaces on a bare metal chip. The metal chip includes a metal interconnect formed on a semiconductor substrate and at least a portion of the metal interconnect is exposed to the environment. The process further comprises depositing a layer of solder particles of a low melting point metal whose temperature is relatively low on the portion of exposed metal interconnect. The process also comprises converting the layer of the solder particles to a bondable layer compatible with a wire bonding, and bonding a metal wire to the bondable layer.

Still another aspect of the present invention is to provide a process of forming metal surfaces on a bare metal chip. The metal chip includes a metal interconnect formed on a semiconductor substrate and at least a portion of the metal interconnect is exposed to the environment. The process further comprises depositing a layer of solder particles of a noble metal or an alloy thereof on the portion of exposed metal interconnect. The process also comprises converting the layer of the solder particles to a bondable layer compatible with a wire bonding, and bonding a metal wire to the bondable layer.

### BRIEF DESCRIPTION OF THE DRAWINGS

FIG. 1 is a schematic view of a conventional wire bonding system.

FIG. 2 is a schematic view of another conventional wire bonding system.

FIG. 3 is a schematic view of still another conventional wire bonding system.

FIG. 4a is a schematic view of a manufactured copper chip.

FIG. 4b is a schematic view as shown in FIG. 4a, but adding a bondable layer to the copper interconnect according to the present invention.

FIG. 5 is a schematic view of one embodiment according to the invention.

FIGS. 6a and 6b are schematic views of another embodiment according to the invention.

FIGS. 7a and 7b are schematic views of another embodiment according to the invention.

FIGS. 8a and 8b are schematic views of still another embodiment according to the invention.

FIG. 9 is a schematic view of a semiconductor circuit in which the embodiment of the invention can be implemented.

FIG. 10a is a schematic view of a manufactured copper chip.

FIGS. 10b and 11 are schematic views for comparing a conventional wire bonding system and the wire bonding system according to the invention.

### DETAILED DESCRIPTION OF THE CERTAIN INVENTIVE EMBODIMENTS

This invention relates to a process of forming metal surfaces in a semiconductor device with metal interconnects such as copper (Cu) interconnects, copper alloy, other possible combination of copper alloys, and other metal interconnects, using conventional Au and Al wire bond tools. The invention may be applied to metallization which is incompatible with conventional wire bonding. By using a suitable low cost intermediate process, according to this invention, a bond pad, which is a part of the Cu interconnect and exposed to the environment, is converted to a bondable layer that can be bonded to a conventional metal wire, such as an Au or Al wire (not shown).

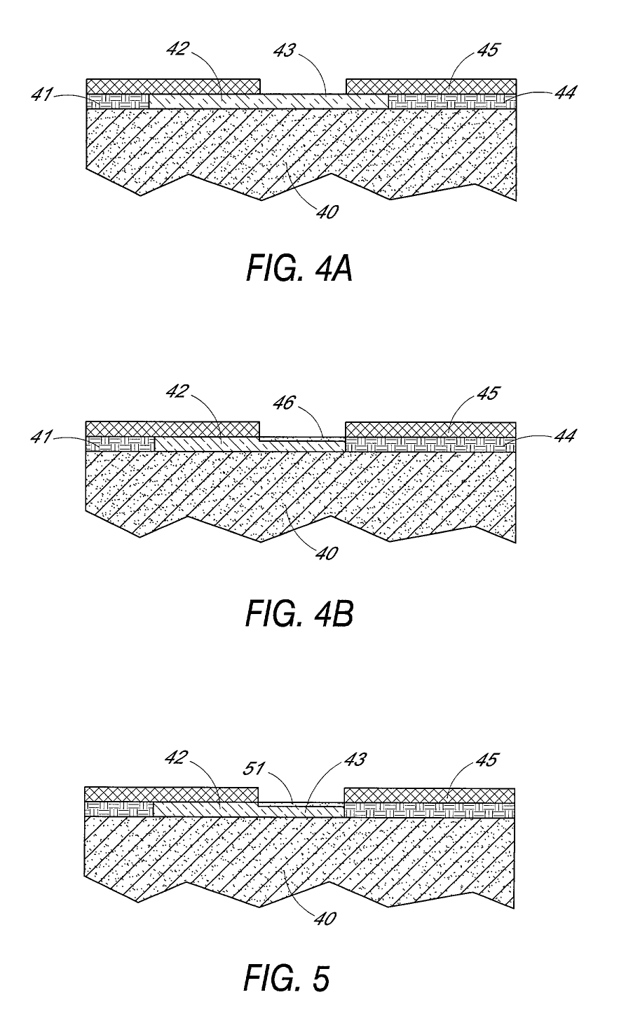

Referring to FIG. 4a, a bare Cu chip with the Cu interconnects 42 (Cu metallization layer) and a passivation layer 45 is shown. The Cu metallization layer 42 can be a single layer or multiple layers and it may also have a suitable barrier and adhesion layers using the conventional copper chip technology or dual damascene process. Reference numerals 41 and 44 refer to a dielectric layer.

Since the present invention is applied to the manufactured chip illustrated in FIG. 4a, no additional process such as masking or etching is required at the front end (chip manufacturing process). A very simple low cost and maskless additional step at the assembly back end (chip packaging process) will convert a bond pad 43 (exposed copper interconnects) into a bondable surface with a bondable layer 46 as shown in FIG. 4b. After the bondable layer 46 is formed, a metal wire (not shown) such as an Au or Al may be bonded to the bondable layer 46 through a conventional wire bonding technique, for example, an ultrasonic wire bonding, a thermosonic wire bonding, a welding or a combination thereof.

The additional process steps may comprise one of the following modes described below:

MODE 1

Referring to FIG. 5, a noble metal (e.g., silver-Ag, gold-Au, platinum-Pt, palladium-Pd, an alloy thereof, etc.) is applied to the bond pad 43 (exposed Cu interconnects), and the bond pad 43 is replaced with a noble metal layer 51 which is a bondable layer compatible with a wire bonding. Here, a simple chemical process such as an immersion silver process, a dip silver process, an electroless silver process, etc., is used to deposit the noble metal layer 51 on the bond pad 43.

Specifically, when the noble metal is applied to the exposed Cu interconnects 43 by the above chemical process, a diffusion occurs on the exposed Cu interconnects 43, which causes Cu atoms of the exposed Cu interconnects 43 and atoms of the noble metal to mix with one another and, thus, the noble metal adheres to the exposed Cu interconnects 43. An immersion silver process is disclosed by others in the following patent documents. U.S. Pat. Nos. 5,733,599 and 5,935,640, which are incorporated by reference. As described in the patents, the process results in an exchange of atoms between the copper and silver resulting in a layer of silver deposit on the Cu metallization.

After the noble metal is adhered to the exposed Cu interconnects 43, conventional wire bonding is carried out on the metalization, and the quality of the wire bond can be evaluated by shear strength. In one of the embodiments, the value of the shear strength falls within the JEDEC qualifying limits. (JEDEC stands for “Joint Electron Device Engineering Council”, and is the semiconductor engineering standardization body of the Electronic Industries Alliance (EIA), a trade association that represents all areas of the electronic industry.) This has been proven by experimentation and the results thereof which are incorporated as Appendix A of this application.

The chemical process may comprise any other processes that satisfy the above results. Also, the noble metal may comprise one or more of the other metals shown in Appendix B, besides Ag, Au, Pt and Pd.

As described above, the process is carried out on a bare semiconductor chip that has already been manufactured, and the process affects only the exposed copper interconnects 43, and hence no mask is required. The noble metal is restricted to adhere only to the Cu interconnects 42, even if masks are not used, because an exchange reaction of atoms does not occur on the passivation layer 45. Even if most of the back end houses are generally not equipped with photolithographic equipment and masks, the process of the invention is very conveniently performed at either a front end or a back end. After this process is completed, the bonding between gold or aluminum wires (not shown) and the noble metal layer can be easily carried out through the conventional way, such as ultrasonic wire bonding, thermosonic wire bonding, a welding or combination thereof, etc.

MODE 2

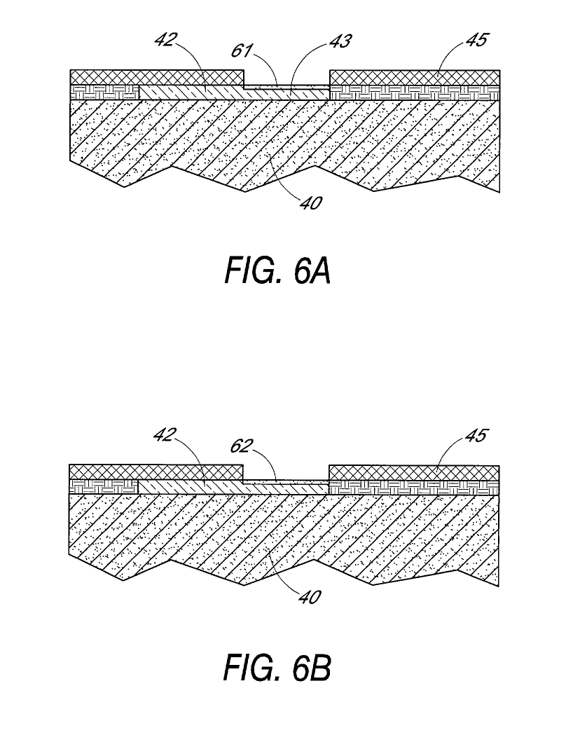

Referring to FIG. 6a, a low melting point metal is applied to the exposed Cu interconnects 43. The low melting point metal means solder materials whose temperature is relatively low (below 350° C.) suitable for soldering purpose. By way of example, the low melting point metal may comprise Tin (Sn), Indium (In), Bismuth (Bi), Lead (Pb), and an alloy thereof, etc. A simple chemical process such as electroless tin, dip tin, electroless bismuth, etc. is used to replace a few mono layers of the exposed Cu interconnects 43 with a thin layer of the low melting point metal 61. The electroless tin process is disclosed in U.S. Pat. No. 3,917,486 and 4,027,055, which are incorporated herein by reference. The simple chemical process also comprises any other processes that satisfy the above results in addition to the electroless tin, dip tin, and electroless bismuth, etc.

After depositing the layer of the low melting point metal 61 over the bond pad 43, a chemical reaction such as sintering and metal replacement, a heat treatment (reflow process, soldering), or combination thereof may be additionally carried out to increase the adhesion of the deposited low melting point metal. The above process including the heat treatment, etc., ensures that the fine solder particles of the low melting point metal are melted and form a thin coat of material over the exposed copper interconnects 43. The heat treatment may convert partially or fully the thin layer of the low melting point metal into an intermetallic bondable layer 62 compatible with a conventional wire bonding. For example, by cooling tin and reflowing it over copper, Cu₆Sn₅, which constitutes the intermetallic bondable layer 62, is formed, However, not all of the low melting point metals need the heat treatment step to form the bondable layer 62. A thin layer of a metal such as In or Bi may form a bondable layer without use of heat treatment. The bondable layer 62 is used for bonding a metal wire with conventional wire bonding. However, the layer 61 of metal, such as In or Bi, which is applied after the simple chemical process, can be directly used for wire bonding without any heat treatment being performed.

The process in MODE 2 is also carried out on a bare semiconductor chip that has already been manufactured as illustrated in FIGS. 6a and 6b, and the process affects only the exposed copper interconnects 42, and hence no mask is required. After this process is done, the bonding between gold or aluminum wires (not shown) and the bondable layer 62 can also be easily carried out in the conventional way, such as ultrasonic wire bonding, thermosonic wire bonding, welding or combination thereof, etc.

MODE 3

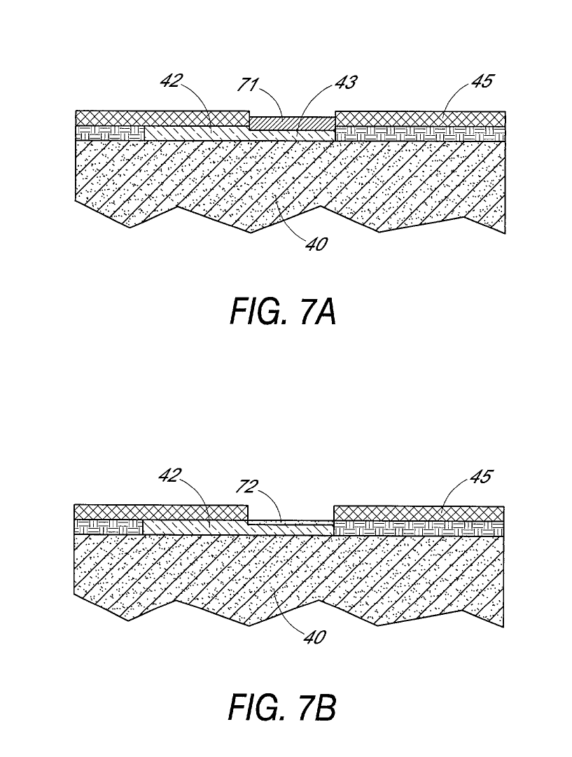

As shown in FIG. 7a, a tacky (sticky) layer 71 is provided on the exposed copper interconnects 43 by known chemical processes. Solder particles formed from low melting point metal are deposited on the tacky layer 71. The solder particles are embedded into the tacky layer 71, thus a layer of the solder particles is formed on the exposed copper interconnects 43. Since the solder particles have been embedded into the tacky layer 71, the layer of the solder particles will also be designated as reference numeral 71 in FIG. 7a.

After the layer 71 is deposited on the bond pad 43, a chemical reaction, a heat treatment (reflow process, soldering), or combination thereof may be additionally carried out to increase the adhesion of the deposited layer of the solder particles. A bondable layer 72 which has undergone the above process (heat treatment, chemical reaction, etc.) is shown in FIG. 7b. The bondable layer 72 is used for bonding a metal wire with conventional wire bonding. However, the layer 71 can be directly used for wire bonding before the heat treatment is performed.

The above processes may be performed by using SUPER JUFFIT process of Showa Denko (http://www.sdk.co.jp) or SUPER SOLDER process of Harima Chemical Inc. (http://www.harima.cojp).

The process described in MODE 3 is also a simple chemical process which can be carried out directly on the exposed copper interconnects 43 without any masks.

MODE 4

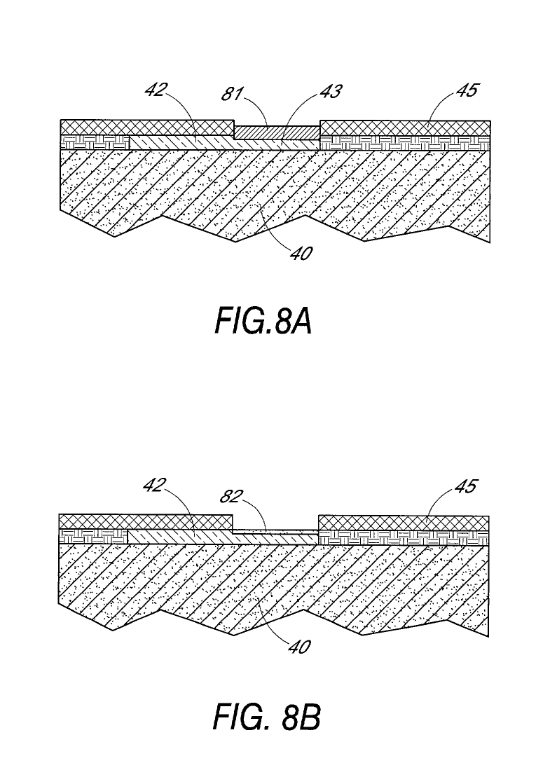

As shown in FIG. 8a, a tacky (sticky) layer 81 is provided on the exposed copper interconnects 43 by known chemical processes. Fine particles of a noble metal or its alloy are deposited on the tacky layer 81. The fine particles are embedded into the tacky layer 81, thus a layer of the fine particles of a noble metal or its alloy is formed on the exposed copper interconnects 43. Since the fine particles have been embedded into the tacky layer 81, the layer of the fine particles will also be designated as reference numeral 81 in FIG. 8a.

After the layer 81 is deposited on the bond pad 43, a chemical reaction, a heat treatment (reflow process, soldering), or combination thereof is carried out in order to form a bondable layer 82 compatible with conventional wire bonding as shown in FIG. 8b. The layer 81 may comprise fine particles of any noble metals or their combination which can be reduced and sintered into a bondable metal layer by a heat treatment or a chemical reaction. The bondable layer 82 is used for bonding a metal wire with conventional wire bonding.

The above processes may be performed by using SUPER JUFFIT process of M/s Showa Denko (http://www.sdk.co.jp) or SUPER SOLDER process of M/sHarima Chemical Inc. (http://www.harima.co.jp).

The process described in MODE 4 is also a simple chemical process which can be carried out directly on the exposed copper interconnects 43 without any masks. MODES 1 and 4 may be further described.

A wire bonding or a bare Cu chip is a back end or assembly house issue. In the prior art, the process could only be carried out in a semiconductor chip fabrication house, which uses a costlier sputtering and etching tool. The prior art involves sputtering an aluminum layer on copper, and then carrying out the passivation and sending it to assembly houses for wire bonding. However, in the present invention the same process is carried out on a bare Cu chip which has already been sent to the assembly house. It is a simple chemical process which converts the exposed copper layer into a bondable layer, thus permitting a wire bonding using conventional Au and Al wire bonders.

Furthermore, the process according to the invention can also be additionally applied to any structure formed on the semiconductor substrate on which the wire bonding is carried out. The structure includes any shape or form (e.g. thick, thin, round, square, with via, etc.) that a bond pad tae. Also, it is not strictly restricted to conventional bond pads alone. In addition, the structure includes any device surface on which the process provided by the process of the invention is applied.

MODE 5

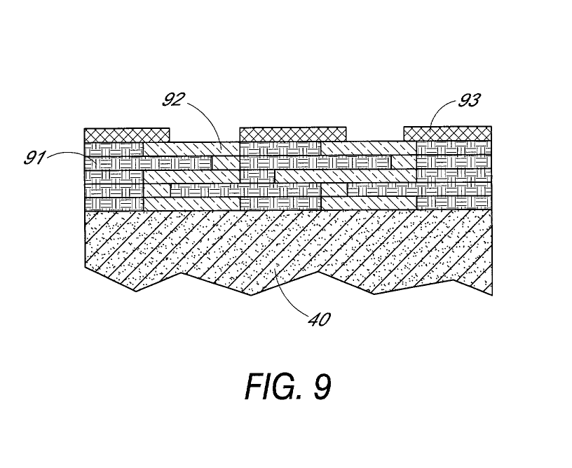

As illustrated in FIG. 9, the above processes and methods described in MODE 1 to MODE 4 can also be implemented on multilayer advanced copper interconnects with a low K dielectric 91 and a passivation layer 93. The low K dielectric 91 may be, by way of example, comprises SiLK®, Black Diamond®, and Coral®. Also, the range of the low K dielectric 91 may be between 0-3. Reference numeral 92 in FIG. 9 indicates a Cu interconnects.

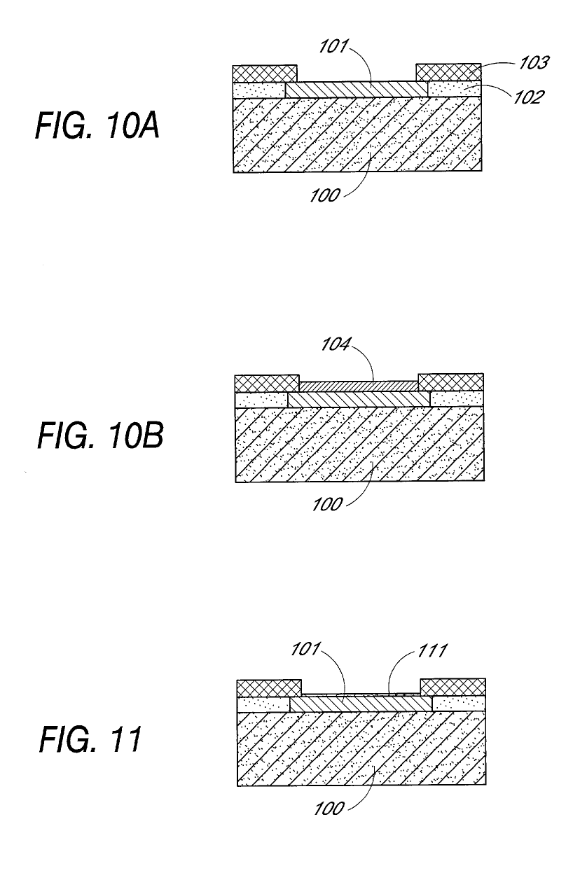

FIGS. 10a-11 are drawings for comparing the prior art and the present invention. FIG. 10a illustrates a conventional bare Cu chip. FIG. 10b illustrates one of the prior wire bonding techniques that use Al cap metallization. FIG. 11 illustrates a wire bonding technique according to the present invention.

FIG. 10a is substantially the same as FIG. 4a. A silicon wafer 100 and an oxide/dielectric layer 102 in FIG. 10a corresponds to a silicon layer 40 and a dielectric 41 in FIG. 4a. A Cu metallization 101 in FIG. 10a corresponds to the Cu interconnects 42 shown in FIG. 4a.

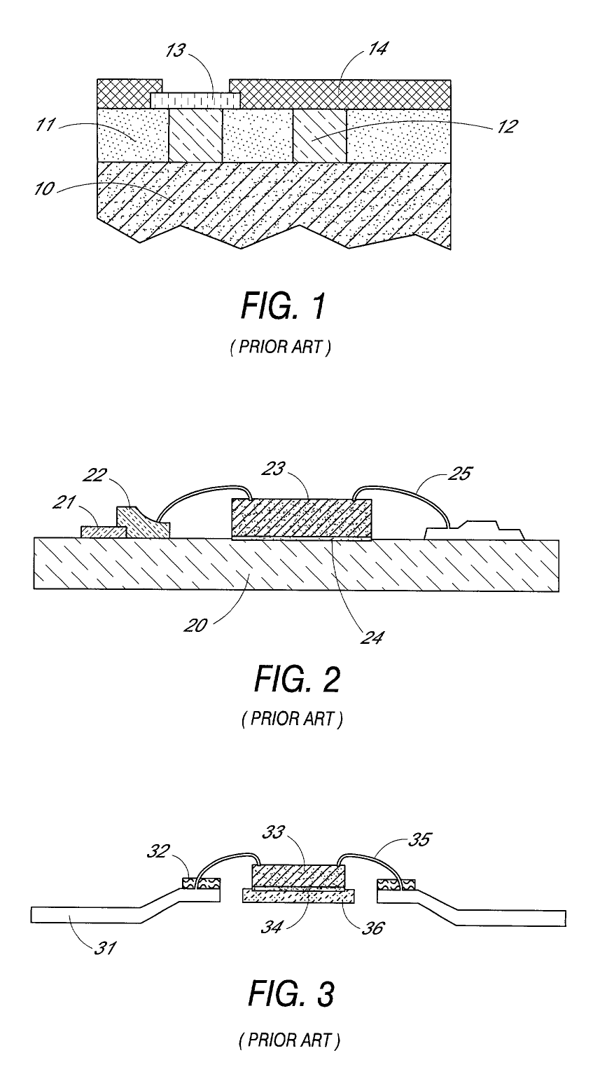

FIG. 10b is substantially the same as FIG. 1. An Al cap metallization 104 in FIG. 10b corresponds to an Al pad 13 in FIG. 1. As described before, forming the Al cap metallization on the Cu metallization involves a complicated process such as lithography and chemical etching, resulting in a high manufacturing cost.

FIG. 11 illustrates one embodiment of the present invention. A bondable layer 111 formed by the process of the present invention is compatible with conventional wire bonding technique, such as an ultrasonic wire bonding, a thermosonic wire bonding, a welding or combination thereof. The main difference between the process of FIG. 11 and the process of FIG. 10b is that the process of FIG. 11 uses a simple chemical process to form the bondable layer 111, while the process of FIG. 10b uses a complicated semiconductor fabrication process to form the Al cap metallization 104.

Results

Since the process of the present invention is performed on a processed chip, the present invention has passivation followed by the metallization layer being converted into a bondable layer by the process described in Modes 1-5.

The results of the wire bonding experiments carried out is documented in Appendix A. Page 1/7 of Appendix-A illustrates wire bond process parameters. Page 2/7 of Appendix-A illustrates Pull-strength test results. Page 3/7 of Appendix-A illustrates photographs showing Failure mode of page 2/7 test. Page 4/7 of Appendix-A illustrates Pull-strength test results under 1 time and 4 times reflowing in an oven of 0-260° C. (5 mins) Page 5/7 of Appendix-A illustrates photographs showing Failure mode of page 4/7 test. Page 6/7 of Appendix-A illustrates shear strength test results under (1) time zero and (2) Thermal Cycle −40° C.-125° C., 15 min, interval for 94 cycles. Page 7/7 of Appendix-A illustrates Pull-strength test results under 150° C. for 1 hour, before gold ball bonding and 240 hours, before wedge bonding respectively. All the data of Appendix-A are based on MODE 1.

In summary, the values of wire bond pull strength and shear strength by the wire bonding of the invention are equivalent to the values achieved by conventional wire bonding. Also, referring to page 2/7 of Appendix-A, it can be seen that no degradation has occurred. Page 2/7 of Appendix-A shows Pull strength tests under (1) Time Zero; (2) HTS—High Temperature Storage (150° C. for 240 hours); and (3) Thermal Cycle: 40° C.-125° C., 15 mins. for 94 cycles. Comparison of the average pull strength results, (1) 9.515, (2) 9.015 and (3) 9.568 on page 2/7 of Appendix-A shows no substantial degradation. Hence, this technique can be widely applied to carry out conventional wire bonding on Cu-chips.

### CERTAIN ADVANTAGES OF THE INVENTION

The present invention is so simple, it can be easily applied to finished semiconductor devices with Cu metallization. It generally does not require any additional processes in the front end.

The present process is so flexible that it can be easily incorporated either at front-end or in the backend assembly

The present process is a simple method which can be carried out directly on the finished die. No additional masks are required for the fabrication and this reduces the cost drastically.

The other main advantage of this process is that it can be carried out at a die or wafer level. All other known prior art processes can only be carried out only on wafer level.

The process is suitable for both mass scale production as well as small-scale production.

The novelty of the process is such that it also allows the user to subject to all other temperature applied to the real package assembly process, which may cause oxidation of the copper metallization, such as die bonding process, reflow component attach process, etc.

Lastly, this inventive process is not labor intensive.

Thus, there has been described a new wire bonding process and structure. While the preferred embodiment of the invention has been shown, apparently many changes and modifications may be made therein without departing from the scope of the invention. It is appreciated, therefore, that the appended claims cover any and all such changes and modifications which do not depart from the true spirit and scope of the invention.

[image]

[image]

[image]

[image]

[image]

[image]

[image]

[image]

What is claimed is:

1. A process of forming metal surfaces on a bare metal chip, the metal chip comprising at least one metal interconnect formed on a semiconductor substrate, at least a portion of the metal interconnect being exposed to the environment, the process comprising:
applying a metal on the exposed portion of the metal interconnect;
performing a maskless chemical process that converts a layer of the metal into a bondable layer compatible with a wire bonding; and
bonding a metal wire to the bondable layer.

2. The process of claim 1, wherein the at least one metal interconnect is substantially copper.

3. The process of claim 1, wherein the metal wire comprises aluminum or gold or metal alloy.

4. The process of claim 1, wherein the bonding is performed by an ultrasonic wire bonding, a thermosonic wire bonding, a welding or combination thereof.

5. The process of claim 1, wherein the semiconductor substrate is selected from the group consisting of: silicon, GaAs, and Inp.

6. The process of claim 1, wherein the process is additionally applied to any structure formed on the semiconductor substrate on which the wire bonding is carried out.

7. A process of forming metal surfaces on a bare metal chip, the metal chip comprising at least one metal interconnect formed on a semiconductor substrate, at least a portion of the metal interconnect being exposed to the environment, the process comprising:
applying a noble metal on the exposed portion of the metal interconnect;
performing a chemical process that causes a layer of the noble metal to convert into a bondable layer compatible with a wire bonding; and
bonding a metal wire to the bondable layer.

8. The process of claim 7, wherein the chemical process causes atoms of the noble metal to be diffused and mixed with metal atoms of the metal interconnect.

9. The process of claim 8, wherein the chemical process comprises one of the following: an immersion process, a dip process or an electroless process.

10. The process of claim 7, wherein the noble metal substantially comprises Ag, Au, Pd, Pt, Ru, Rh, Re, Os, Ir or any alloy thereof.

11. The process of claim 7, wherein the at least one metal interconnect is substantially copper.

12. The process of claim 7, wherein the metal wire comprises aluminum or gold or metal alloy.

13. The process of claim 7, wherein the bonding is performed by an ultrasonic wire bonding, a thermosonic wire bonding, a welding or combination thereof.

14. The process of claim 7, wherein the semiconductor substrate is selected from the group consisting of: silicon, GaAs, and InP.

15. The process of claim 7, wherein the process is additionally applied to any structure formed on the semiconductor substrate on which the wire bonding is carried out.

16. A process of forming metal surfaces on a bare metal chip, the metal chip comprising at least one metal interconnect formed on a semiconductor substrate, at least a portion of the metal interconnect being exposed to the environment, the process comprising:
depositing a layer of a noble metal on the exposed portion of the metal interconnect;
converting the layer of the noble metal to a bondable layer compatible with a wire bonding by a chemical process; and
bonding a metal wire to the bondable layer.

17. The process of claim 16, wherein the chemical process comprises an immersion process, a dip silver process and an electroless process.

18. The process of claim 16, wherein the at least one metal interconnect is substantially copper.

19. The process of claim 16, wherein the metal wire comprises aluminum or gold.

20. The process of claim 16, wherein the bonding is performed by an ultrasonic wire bonding, a thermosonic wire bonding, a welding or combination thereof.

21. The process of claim 16, wherein the semiconductor substrate is selected from the group consisting of: silicon, GaAs, and InP.

22. The process of claim 16, wherein the process is additionally applied to any structure formed on the semiconductor substrate on which the wire bonding is carried out.

23. A process of forming metal surfaces on a bare metal chip, the metal chip comprising at least one metal interconnect formed on a semiconductor substrate, at least a portion of the metal interconnect being exposed to the environment, the process comprising:
forming a layer of a low melting point metal whose melting temperature is relatively low on the exposed portion of the metal interconnect;
converting the layer of the low melting point metal into a bondable layer compatible with a wire bonding by a chemical process; and
bonding a metal wire to the bondable layer.

24. The process of claim 23, wherein the chemical process comprises an electroless tin process, a dip tin process and an electroless bismuth process.

25. The process of claim 23, wherein the at least one metal interconnect is substantially copper.

26. The process of claim 23, wherein the metal wire comprises aluminum or gold.

27. The process of claim 23, wherein the bonding is performed by an ultrasonic wire bonding, a thermosonic wire bonding, a welding or combination thereof.

28. The process of claim 23, further comprising performing a chemical reaction, a heat treatment or combination thereof on the bondable layer in order to increase the adhesion of the bondable layer on the exposed portion of the metal interconnect.

29. The process of claim 23, wherein the melting temperature is below 350° C.

30. The process of claim 23, wherein the semiconductor substrate is selected from the group consisting of: silicon, GaAs, and InP.

31. The process of claim 23, wherein the process is additionally applied to any structure formed on the semiconductor substrate on which the wire bonding is carried out.

32. A process of forming an electrical connection between a metal wire and at least one metal interconnect supported on a semiconductor substrate, the process comprising:
forming the at least one metal interconnect on the semiconductor substrate;
depositing a passivation layer on the metal interconnect, at least a portion of the metal interconnect being exposed to the environment through an opening formed on the passivation layer;
applying a low melting point metal whose melting temperature is relatively low on the exposed portion of the metal interconnect;
converting a layer of the low melting point metal into a bondable layer compatible with a wire bonding on the exposed portion of the metal interconnect; and
bonding a metal wire to the bondable layer.

33. The process of claim 32, wherein the at least one metal interconnect is substantially copper.

34. The process of claim 32, wherein the metal wire comprises aluminum or gold or metal alloy.

35. The process of claim 32, wherein the bonding is performed by an ultrasonic wire bonding, a thermosonic wire bonding, a welding or combination thereof.

36. The process of claim 32, further comprising performing a heat treatment on the bondable layer in order to increase the adhesion of the bondable layer on the exposed portion of the metal interconnect.

37. The process of claim 32, wherein the semiconductor substrate is selected from the group consisting of: silicon, GaAs, and InP.

38. The process of claim 32, wherein the process is additionally applied to any structure formed on the semiconductor substrate on which the wire bonding is carried out.

39. A process of forming metal surfaces on a bare metal chip, the metal chip comprising at least one metal interconnect formed on a semiconductor substrate, at least a portion of the metal interconnect being exposed to the environment, the process comprising:
forming a layer of solder particles of a low melting point metal whose temperature is relatively low on the exposed portion of the metal interconnect;
converting the layer of the solder particles into a bondable layer compatible with a wire bonding; and
bonding a metal wire to the bondable layer.

40. The process of claim 39, wherein the at least one metal interconnect is substantially copper.

41. The process of claim 39, wherein the metal wire comprises aluminum or gold.

42. The process of claim 39, wherein the bonding is performed by an ultrasonic wire bonding, a thermosonic wire bonding, a welding or combination thereof.

43. The process of claim 39, further comprising performing a chemical reaction, a heat treatment or combination thereof on the bondable layer in order to increase the adhesion of the bondable layer on the exposed portion of the metal interconnect.

44. The process of claim 39, wherein the semiconductor substrate is selected from the group consisting of: silicon, GaAs, and InP.

45. The process of claim 39, wherein the process is additionally applied to any structure formed on the semiconductor substrate on which the wire bonding is carried out.

46. The process of claim 39, wherein the forming comprises:
providing a tacky layer on the exposed portion of the metal interconnect; and
applying the solder particles of the low melting point metal on the tacky layer, thus forming the layer of the solder particles.

47. A process of forming metal surfaces on a bare metal chip, the metal chip comprising at least one metal interconnect formed on a semiconductor substrate, at least a portion of the metal interconnect being exposed to the environment, the process comprising:
forming a layer of fine particles of a noble metal or an alloy thereof on the exposed portion of the metal interconnect;
converting the layer of the solder particles into a bondable layer compatible with a wire bonding on the exposed portion of the metal interconnect by performing a chemical reaction, a heat treatment or combination thereof on the layer of fine particles; and
bonding a metal wire to the bondable layer.

48. The process of claim 47, wherein the at least one metal interconnect is substantially copper.

49. The process of claim 47, wherein the metal wire comprises aluminum or gold.

50. The process of claim 47, wherein the bonding is performed by an ultrasonic wire bonding, a thermosonic wire bonding, a welding or combination thereof.

51. The process of claim 47, wherein the forming comprises:
providing a tacky layer on the exposed portion of the metal interconnect; and
applying the fine particles on the tacky layer, thus forming the layer of the fine particles.

52. The semiconductor integrated circuit of claim 47, wherein the semiconductor substrate is selected from the group consisting of: silicon, GaAs, and InP.

53. A semiconductor integrated circuit, comprising:
a bare semiconductor chip comprising;
a semiconductor substrate; and
a metal interconnect formed on the semiconductor substrate, at least a portion of the metal interconnect being exposed to the environment;
a layer of a noble metal formed on the portion of the metal interconnect, and compatible with a wire bonding; and
a metal wire bonded to the layer of the noble metal.

54. The semiconductor integrated circuit of claim 53, wherein the noble metal substantially comprises Ag, Au, Pd, Pt, Ru, Rh, Re, Os, Ir or any alloy thereof.

55. The semiconductor integrated circuit of claim 53, wherein the metal interconnect comprises a copper.

56. The semiconductor integrated circuit of claim 53, wherein the metal wire comprises an aluminum wire or a gold wire or metal alloy wire.

57. The semiconductor integrated circuit of claim 53, wherein the semiconductor substrate is selected from the group consisting of: silicon, GaAs, and InP.

58. A semiconductor integrated circuit, comprising:
a bare semiconductor chip comprising;
a semiconductor substrate; and
a metal interconnect formed on the semiconductor substrate, at least a portion of the metal interconnect being exposed to the environment;
a layer of a low melting point metal formed on the exposed portion of the metal interconnect, and compatible with a wire bonding, a melting temperature of the low melting point metal being relatively low; and
a metal wire bonded to the layer of the low melting point metal.

59. The semiconductor integrated circuit of claim 58, wherein the low melting metal comprises Sn, In, Bi, Pb and an alloy thereof.

60. The semiconductor integrated circuit of claim 58, wherein the metal interconnect comprises a copper.

61. The semiconductor integrated circuit of claim 58, wherein the metal wire comprises an aluminum wire or a gold wire.

62. The semiconductor integrated circuit of claim 58, wherein the melting temperature is below 350° C.

63. The semiconductor integrated circuit of claim 58, wherein the semiconductor substrate is selected from the group consisting of: silicon, GaAs, and InP.

64. A semiconductor integrated circuit, comprising:
a bare semiconductor chip comprising;
a semiconductor substrate; and
a metal interconnect formed on the semiconductor substrate, at least a portion of the metal interconnect being exposed to the environment;
a layer of solder particles of a low melting point metal formed on the exposed portion of the metal interconnect, and compatible with a wire bonding, a melting temperature of the low melting point metal being relatively low; and
a metal wire bonded to the layer of solder particles.

65. The semiconductor integrated circuit of claim 64, wherein the low melting point metal comprises Sn, In, Bi, Pb and an alloy thereof.

66. The semiconductor integrated circuit of claim 64, wherein the metal interconnect comprises a copper.

67. The semiconductor integrated circuit of claim 64, wherein the metal wire comprises an aluminum wire or a gold wire.

68. The semiconductor integrated circuit of claim 64, wherein the melting temperature is below 350° C.

69. The semiconductor integrated circuit of claim 64, wherein the semiconductor substrate is selected from the group consisting of: silicon, GaAs, and InP.

70. A semiconductor integrated circuit, comprising:
a bare semiconductor chip comprising;
a semiconductor substrate; and
a metal interconnect formed on the semiconductor substrate, at least a portion of the metal interconnect being exposed to the environment;
a layer of particles of a noble metal or an alloy thereof formed on the exposed portion of the metal interconnect and compatible with a wire bonding; and
a metal wire bonded to the layer of solder particles.

71. The semiconductor device of claim 70, wherein the noble metal substantially comprises Ag, Au, Pd, Pt, Ru, Rh, Re, Os or Ir.

72. The semiconductor integrated circuit of claim 70, wherein the metal interconnect comprises a copper.

73. The semiconductor integrated circuit of claim 70, wherein the metal wire comprises an aluminum wire or a gold wire.

74. The semiconductor integrated circuit of claim 70, wherein the semiconductor substrate is selected from the group consisting of: silicon, GaAs, and InP.

75. A semiconductor integrated circuit, comprising:
a bare semiconductor chip comprising;
a semiconductor substrate; and
a metal interconnect formed on the semiconductor substrate, at least a portion of the metal interconnect being exposed to the environment;
a layer of a metal formed on the portion of the metal interconnect by a maskless chemical process, and compatible with a wire bonding; and
a metal wire bonded to the layer of the metal.

76. The semiconductor integrated circuit of claim 75, wherein the metal interconnect comprises a copper.

77. The semiconductor integrated circuit of claim 75, wherein the metal wire comprises an aluminum wire or a gold wire or metal alloy wire.

78. The semiconductor integrated circuit of claim 75, wherein the semiconductor substrate is selected from the group consisting of: silicon, GaAs, and InP.
